(19) United States
(12) Patent Application Publication
(10) Pub. No.: US 2009/0066825 A1
(43) Pub. Date: Mar. 12, 2009

(54) SOLID-STATE IMAGING DEVICE AND ITS DRIVING METHOD

(75) Inventors: Shinsuke Nezaki, Kyoto (JP); Masashi Murakami, Kyoto (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 11/718,556

(22) PCT Filed: Feb. 27, 2006
(86) PCT No.: PCT/JP2006/303628

§ 371 Date: May 3, 2007

(30) Foreign Application Priority Data
Feb. 28, 2005 (JP) 2005-052846

(51) Int. Cl. H04N 5/335

(52) U.S. Cl. 348/308; 348/E05.091

(57) ABSTRACT

A driving method is used in a solid-state imaging device including a plurality of pixel circuits which are arranged in rows and columns, and each of which has a photoelectric conversion unit and a charge accumulation unit and receives a common power source. The driving method includes steps of: reading out, to the outside of the pixel circuit, a photocharge generated at a photoelectric conversion unit in a pixel circuit in a readout row, after resetting a potential of the charge accumulation unit in the pixel circuit to a potential of the common power source while supplying a bias current to the pixel circuit for readout, the photocharge being transferred to the charge accumulation unit as a signal charge; discharging a photocharge generated at a photoelectric conversion unit in a pixel circuit in a discharge row that is to be a readout row later, after resetting a potential of a charge accumulation unit in the pixel circuit to a potential of the common power source, the photocharge being transferred to the charge accumulation unit as an unnecessary charge; and uniformizing a potential of the charge accumulation unit to be reset in the discharging in the case where the discharging is executed following the reading out and in the case where the discharging is executed independently

### TECHNICAL FIELD

The present invention relates to a solid-state imaging device and a driving method thereof, and particularly to a technique for suppressing an image defect in a solid-state imaging device having an electronic shutter that provides each pixel with a common pixel power source.

### BACKGROUND ART

In recent years, a solid-state imaging device using an amplification MOS sensor has been attracting attention as a solid-state imaging device. In this solid-state imaging device, a photodiode detects signal at every cell representing a pixel, and a transistor amplifies the signal. Consequently, the solid-state imaging device is characterized by supersensitivity.

As an example of such a solid-state imaging device, patent reference 1 has proposed a solid-state imaging device that has pixels arranged two-dimensionally and that is capable of selecting or deselecting the pixels without a transfer selection switch being provided.

Moreover, patent reference 2 has proposed a configuration that standardizes a reset power source and a pixel power source on such a solid-state imaging device.

FIG. 10 is a circuit configuration showing an example of the configuration of the conventional solid-state imaging device based on patent reference 2.

Hereinafter, a pixel readout operation and a reset operation performed by the circuit shown in FIG. 10 will be described in detail. Note that this description will be complemented, to a limited extent, by adding a driving method described on patent references 3 and 4 to the configuration shown in the patent reference 2.

The solid-state imaging device includes plural pixel circuits (10-m . . . 10-n . . . ), each of which is made up of a photodiode 11, a transfer transistor 12, a reset transistor 13, an amplification transistor 14, and a floating diffusion unit 15 connected directly with a gate of the amplification transistor 14. The plural pixel circuits are arranged in rows and columns.

The photodiode 11 and the floating diffusion unit 15 shall be referred to by their respective abbreviations, a PD unit and an FD unit.

The solid-state imaging device further includes a vertical driving unit 112 that drives each pixel circuit per row by providing reset signal on reset switch lines 102-m and 102-n to control the reset transistor 13 as well as by providing transfer signal on transfer switch lines 102-m and 102-n to control the transfer transistor 12. Furthermore, the solid-state imaging device includes: a vertical signal output line 109; a horizontal signal line 110; a horizontal selection transistor 111; a horizontal driving unit 113; a pixel power source 101; a bias current control line 106; a bias current control transistor 107; a constant current source 108 that supplies an electrical current to the bias current control transistor 107; and a timing generator 114.

Note that, for brevity, only pixel circuits by two rows and two columns are shown in FIG. 10 as a group of pixels 104 in the solid-state imaging device, and accordingly the reset switch lines and the transfer switch lines are shown only for two rows.

A general solid-state imaging device adopts the electronic shutter for electronic exposure. After performing an unnecessary charge discharge operation for discharging a photocharge in a photodiode as an unnecessary charge beforehand, the solid-state imaging device performs an electronic shutter operation for allowing a charge accumulation period of the photodiode in each pixel circuit to vary by transferring the photocharge from the photodiode after a controllable period. Since the photocharge accumulated in the photodiode after the unnecessary charge discharge operation is readout as a signal charge per row, the electronic shutter operation is also performed per row.

In particular, both the unnecessary charge discharge operation and the signal charge readout operation include an operation that transfers the photocharge from the photodiode 11 to the floating diffusion unit 15 after the floating diffusion unit 15 is reset to a potential of the pixel power source 101. The transferred photocharge is not readout during the unnecessary charge discharge operation but is readout through the vertical signal output line 109 during the signal charge readout operation.

After the unnecessary charge discharge operation is performed on each row, accumulation of the photocharge to be the signal charge is newly started, and the signal charge readout operation is performed after a predetermined period. As a result, photodiodes that receive the same intensity of incoming light theoretically accumulate the same amount of the signal charge on any row.

Note that the unnecessary charge discharge operation related to the electronic shutter can be called a discard operation, and both terms are synonymous.

FIG. 11 is a schematic diagram showing control of the solid-state imaging device shown in FIG. 10. FIG. 11A shows an example of a detailed configuration for vertical driving, and FIG. 11B shows driving timing.

In FIG. 11, a readout row selection unit 20, a discharge row selection unit 30, and a selection unit 40 are an example of a detailed interior configuration of the vertical driving unit 112. The readout row selection unit 20 is, for example, a shift resistor, and rotates a first bit that indicates a readout row where the photocharge generated in the photodiode is to be readout as the signal charge.

The discharge row selection unit 30 is, for example, a shift resistor, and rotates a second bit preceding the first bit by a predetermined number of rows (i.e. a predetermined phase). The second bit indicates a discharge row where the photocharge generated in the photodiode is to be discharged as the unnecessary charge.

Selectively providing the reset switch lines and the transfer switch lines of the respective rows indicated by the first bit and the second bit, respectively, with the reset signal and the transfer signal, the selection unit 40 provides the bias current control line 106 with bias driving signal for controlling supply and suspension of a bias current.

The timing generator 114 generates the reset signal and the transfer signal to be provided by the selection unit 40, and also controls the circulation of and phase difference between the first bit and the second bit at the readout row selection unit 20 and the discharge row selection unit 30.

In more detail, as shown in FIG. 11B, during a readout period, the selection unit 40 provides the row selected by the readout row selection unit 20 with the readout row reset signal to turn on the reset transistor 13, thereby resetting the FD unit 15 to the potential of the pixel power source 101; and provides it with the readout row transfer signal to turn on the transfer transistor 12, thereby transferring the photocharge from the PD unit 11 to the FD unit 15. During that period, bias current driving signal is provided, and the photocharge transferred to the FD unit 15 is readout as the signal charge through the vertical signal output line 109.

Likewise, during a subsequent discharge period, the selection unit 40 provides the row indicated by the discharge row selection unit 30 with the discharge row reset signal to reset the FD unit 15 and with the discharge row transfer signal to transfer the photocharge from the PD unit 11 to the FD unit 15. Since this photocharge is read and discharged, the PD unit 11 discards it.

A set of operations—the signal charge readout operation at the readout row selected by the readout row selection unit 20 and the ensuing unnecessary charge discharge operation at the discharge row selected by the discharge row selection unit 30—is performed sequentially and cyclically on each row. As a result, after a predetermined period, the signal charge readout operation is performed on the row where the unnecessary charge discharge operation has been performed, and the electronic shutter operation is realized.

In FIG. 11A, an extended section having no corresponding row to be driven is shown at the bottom of the readout row selection unit 20 and the discharge row selection unit 30. While the first bit circulating in the readout row selection unit 20 is at the extended section, the signal charge readout operation is not performed on any row. Furthermore, while the second bit circulating in the discharge row selection unit 30 is at the extended section, the unnecessary charge discharge operation is not performed on any row.

As shown in FIG. 12A, a period in which a bit circulating in the readout row selection unit 20 is at the extended section is specifically called a vertical blanking period (vertical blanking interval), and other period is distinguished by calling it a valid pixel period. The unnecessary charge discharge operation is performed independently during the vertical blanking period, not ensuing the signal charge readout operation.

The vertical blanking period is generally assigned to a period for processing signal of a digital signal processor in the solid-state imaging device.

During the vertical blanking period, as shown in FIG. 12B, the selection unit 40 does not provide any row with the readout row reset signal and the readout row transfer signal but provides an upper row with the discharge row reset signal and the discharge row transfer signal. This is the electronic shutter operation for the upper row of a next frame. Repeating the above described operations during the valid pixel period and the vertical blanking period facilitates readout of the signal charge by the electronic shutter.

### Patent Reference 1: Japanese Laid-Open Patent Application No. 11-112018

### Patent Reference 2: Japanese Laid-Open Patent Application No. 2003-309770

### Patent Reference 3: Japanese Laid-Open Patent Application No. 2003-46864

### Patent Reference 4: Japanese Laid-Open Patent Application No. 2003-46865

### DISCLOSURE OF INVENTION

### Problems that Invention is to Solve

However, according to the conventional configuration, there is a following problem: an FD unit in a row where the signal charge readout operation is ensued by the unnecessary charge discharge operation during the valid pixel period and an FD unit in another row where the unnecessary charge discharge operation is performed independently without ensuing the signal charge readout operation during the vertical blanking period are reset to different potentials.

This means that the potentials to be reset in the FD units receiving the unnecessary charge before PD units discharge the unnecessary charge differ between the former row and the latter row. Consequently, a difference in a residual amount of the unnecessary charge made in the FD unit in each row causes a lateral band of an image lag on an image to become easier to be perceived, which results in a bad image quality.

The nonuniformity of the reset potential in the FD units occurs as follows.

FIG. 13 is a circuit configuration of the conventional solid-state imaging device. Analogous to FIG. 10, FIG. 13 differs from FIG. 10 in that a resistance component 105 on a circuit wiring which supplies the pixel power source to the amplification transistor 14 is depicted.

FIG. 14 is a diagram for showing potential drop of the pixel power source caused by a bias current I0 and a resistance R105 on a power source line. FIG. 14 shows a state of the potential in three periods respectively: in a period (i), since the bias current I0 flows from the constant current source 108, the potential of the pixel power source gets lowered by I0×R105 due to a voltage drop occurred at the resistance component 105 on the circuit wiring; in another period (ii), as the bias current does not flow, the lowered potential of the pixel power source is in transition to return to normal; and, in still another period (iii), the potential of the pixel power source is at the normal potential.

FIG. 15A is a timing chart showing the driving timing and the potential change of the pixel power source of the conventional solid-state imaging device during the valid pixel period. FIG. 15B is a diagram showing the potential change in the FD unit in terms of the discharge row where the unnecessary charge is discharged during the valid pixel period.

In the operations shown in FIG. 15A, since the photocharge is readout from the readout row selected by the readout row selection unit 20 and the electrical current is flown in the resistance component 105 shown in FIG. 13, the potential of the pixel power source 101 is low. Moreover, since the pixel power source 101 is connected commonly to each row, an effect of the potential lowering also extends to the discharge rows.

Therefore, as shown in FIG. 15A, at a time Ta, which corresponds to the period (ii) shown in FIG. 14, the lowered potential of the pixel power source in the FD unit in the discharge row is reset to a potential Vb (<Va), which is in transition to a normal potential Va, by the discharge row reset signal.

FIG. 16A is a timing chart showing the driving timing and the potential change of the pixel power source in the conventional solid-state imaging device during the vertical blanking period. FIG. 16B is a diagram depicting the potential change in the FD unit in terms of the discharge row where the unnecessary charge is discharged during the vertical pixel period.

In the operations shown in FIG. 16A, neither the readout row reset signal nor the readout row transfer signal is provided, and the potential lowering of the pixel power source caused by the readout of the readout row in the operations shown in FIG. 15A does not occur.

Therefore, as shown in FIG. 16A, at a time Tb, the potential in the FD units in the discharge row is reset to the normal potential Va (>Vb) of the pixel power source by the discharge row reset signal.

As described above, the potential after reset differs between the FD unit of the pixel circuit in the row where the unnecessary charge is discharged during the valid pixel period and the FD unit of the pixel circuit in another row where the unnecessary charge is discharged during the vertical blanking period. Consequently, in comparison of FIG. 15B with FIG. 16B, the unnecessary charge tends to remain in the photodiode 11 in the former row more than in the latter row during the ensuing transfer of the photocharge.

Furthermore, differing amount of a residual charge in each row causes the lateral band of the image lag to be perceived, and accordingly the image defect occurs.

With the view to the above problems, an object of the present invention is to provide a technique for reducing the image lag and suppressing the image defect of the solid-state imaging device having the electronic shutter that provides plural pixel circuits with the common pixel power source.

### Means to Solve the Problems

In order to solve the above problems, a driving method is used in a solid-state imaging device of the present invention including a plurality of pixel circuits which are arranged in rows and columns and have a common power source, and each of which has a photoelectric conversion unit and a charge accumulation unit, and the driving method includes the steps of: reading out, to the outside of the pixel circuit, a photocharge generated at a photoelectric conversion unit in a pixel circuit in a readout row, after resetting a potential of the charge accumulation unit in the pixel circuit to a potential of the common power source while supplying a bias current to the pixel circuit for readout, the photocharge being transferred to the charge accumulation unit as a signal charge; discharging a photocharge generated at a photoelectric conversion unit in a pixel circuit in a discharge row that is to be a readout row later, after resetting a potential of a charge accumulation unit in the pixel circuit to a potential of the common power source, the photocharge being transferred to the charge accumulation unit as an unnecessary charge; and uniformizing a potential of the charge accumulation unit to be reset in the discharging in the case where the discharging is executed following the reading out and in the case where the discharging is executed independently.

In the uniformizing, the potential of the charge accumulation unit in the pixel circuit may be reset to the potential of the common power source, prior to the discharging, while the bias current is supplied to the pixel circuit in the discharge row, in the case where the discharging is executed independently.

In the reading out, the potential of the charge accumulation unit in the pixel circuit is reset to the potential of the common power source, and the photocharge generated in the photoelectric conversion unit in the pixel circuit in the readout row is readout, the photocharge being transferred to the charge accumulation unit. In such case, in the uniformizing, the charge accumulation unit in the pixel circuit in the discharge row is preferably reset at a timing which is relatively equal to a timing for resetting the charge accumulation unit in the pixel circuit in the readout row in the reading out.

In the uniformizing, the bias current may be provided to the pixel circuit while resetting the charge accumulation unit in the pixel circuit in the discharge row in the discharging.

In the uniformizing, a period in which the charge accumulation unit in the pixel circuit in the discharge row is reset in the discharging may be extended at least until discharging of the photocharge generated in the photoelectric conversion unit in the pixel circuit starts.

Each of the pixel circuits further includes: a reset switch that is connected between the common power source and the charge accumulation unit; and a transfer switch that is connected between the photoelectric conversion unit and the charge accumulation unit. Providing driving signal to the reset switch causes the charge accumulation unit to be reset, and providing driving signal to the transfer switch can cause photocharge to be transferred from the photoelectric conversion unit to the charge accumulation unit.

Not only can the present invention be realized as such driving method, but also can be realized as a solid-state imaging device that provides the driving signal at distinctive timing indicated by such driving method and that operates in accordance with the driving signal.

### EFFECTS OF THE INVENTION

According to the present invention, after a charge accumulation unit of the pixel circuit in the row where the unnecessary charge is discharged during the valid pixel period and that of the pixel circuit in another row where the unnecessary charge is discharged during the vertical blanking period are reset to the same potential, a photocharge of a photoelectric conversion unit is transferred, as the unnecessary charge, to the charge accumulation unit in each row. Accordingly, resulting from the difference in the reset potential in the charge accumulation unit of each pixel circuit, the difference in the residual charge between the photoelectric conversion units can be eliminated after discharging the unnecessary charge, and thus the occurrence of the image defect due to the image lag can be prevented.

Moreover, in the present invention, merely optimizing the driving signal timing makes the reset potential of the charge accumulation units uniform without adding a new driving circuit or a power source. Accordingly, its practical value is high in that the image defect due to the image lag can be prevented at low cost and with accuracy.

### BRIEF DESCRIPTION OF DRAWINGS

FIG. 1 is a timing chart showing driving timing of each driving signal in a solid-state imaging device according to a first embodiment of the present invention.

FIG. 2A is a timing chart showing time change of a pixel power source and each driving signal during a valid pixel period in the solid-state imaging device according to the first embodiment.

FIG. 2B is a diagram depicting potential change in an FD unit caused by discharge row transfer signal shown in FIG. 2A.

FIG. 3A is a timing chart showing time change of a pixel power source and each driving signal during a vertical blanking period in the solid-state imaging device according to the first embodiment.

FIG. 3B is a diagram depicting potential change in an FD unit caused by discharge row transfer signal shown in FIG. 3A.

FIG. 4 is a timing chart showing driving timing of each driving signal in a solid-state imaging device according to a second embodiment of the present invention.

FIG. 5A is a timing chart showing time change of a pixel power source and each driving signal during a valid pixel period in the solid-state imaging device according to the second embodiment.

FIG. 5B is a diagram depicting potential change in an FD unit caused by discharge row transfer signal shown in FIG. 5A.

FIG. 6A is a timing chart showing time change of a pixel power source and each driving signal during a vertical blanking period in the solid-state imaging device according to the second embodiment.

FIG. 6B is a diagram depicting potential change in an FD unit caused by discharge row transfer signal shown in FIG. 6A.

FIG. 7 is a timing chart showing driving timing of each driving signal in a solid-state imaging device according to a third embodiment of the present invention.

FIG. 8A is a timing chart showing time change of a pixel power source and each driving signal during a valid pixel period in the solid-state imaging device according to the third embodiment.

FIG. 8B is a diagram depicting potential change in an FD unit caused by discharge row transfer signal shown in FIG. 8A.

FIG. 9A is a timing chart showing time change of a pixel power source and each driving signal during a vertical blanking period in the solid-state imaging device according to the third embodiment.

FIG. 9B is a diagram depicting potential change in an FD unit caused by discharge row transfer signal shown in FIG. 9A.

FIG. 10 is a circuit configuration showing a configuration example of a conventional solid-state imaging device.

FIG. 11A shows an example of a detailed configuration for vertical driving in the conventional solid-state imaging device.

FIG. 11B shows a driving timing chart during a valid pixel period.

FIG. 12A shows an example of a detailed configuration for vertical driving in the conventional solid-state imaging device.

FIG. 12B shows a driving timing chart during a vertical blanking period.

FIG. 13 is a circuit configuration showing a resistance on a power source line in the conventional solid-state imaging device.

FIG. 14 is a diagram for describing potential drop of the pixel power source caused by a bias current and a resistance on a power source line.

FIG. 15A is a timing chart showing driving timing and potential change of a pixel power source of the conventional solid-state imaging device during a valid pixel period.

FIG. 15B is a diagram showing potential change in an FD units in terms of a discharge row where the unnecessary charge is discharged during the valid pixel period.

FIG. 16A is a timing chart showing driving timing and potential change of a pixel power source of the conventional solid-state imaging device during a vertical blanking period.

FIG. 16B is a diagram describing potential change in an FD unit in terms of a discharge row where the unnecessary charge is discharged during the vertical pixel period.

### NUMERICAL REFERENCES

10 Pixel circuit
11 Photodiode
12 Transfer transistor
13 Reset transistor
14 Amplification transistor
15 Floating diffusion unit
   20 Readout row selection unit
   30 Discharge row selection unit
   40 Selection unit
   101 Pixel power source
   102 Reset switch line
   103 Transfer switch line
   104 Group of pixels
   105 Resistance component
   106 Bias current control line
   107 Bias current control transistor
   108 Constant current source
   109 Vertical signal output line
   110 Horizontal signal line
   111 Horizontal selection transistor
   112 Vertical driving unit
   113 Horizontal driving unit
   114 Timing generator

### BEST MODE FOR CARRYING OUT THE INVENTION

The following describes embodiments of the present invention with reference to the drawings.

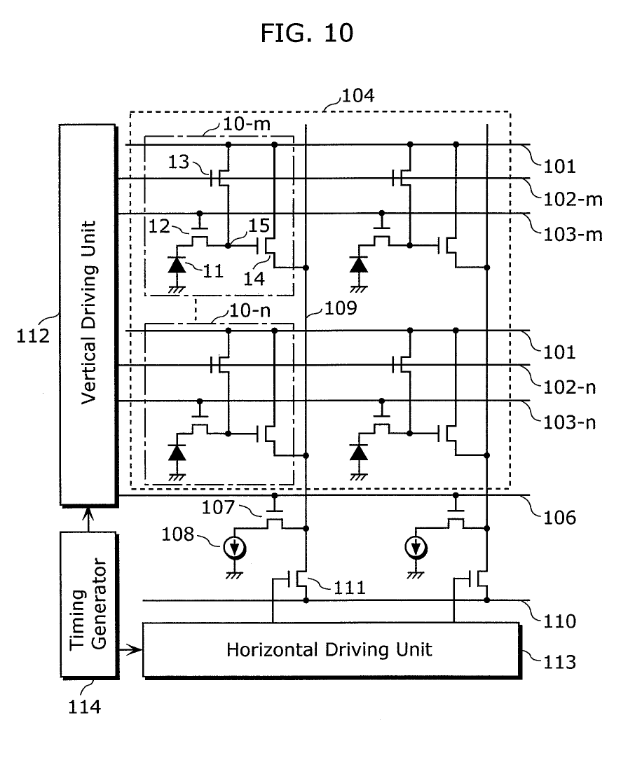

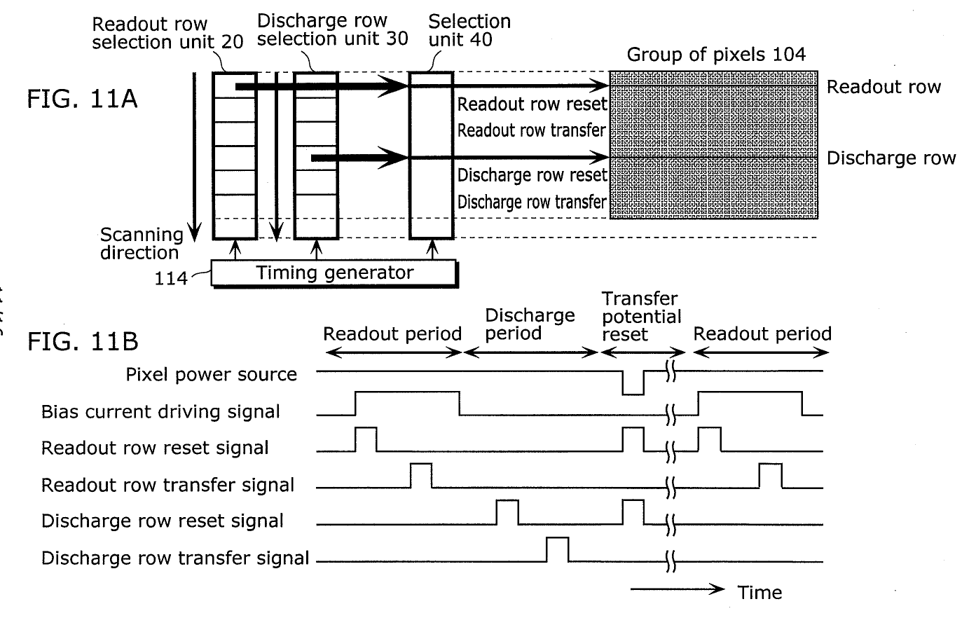

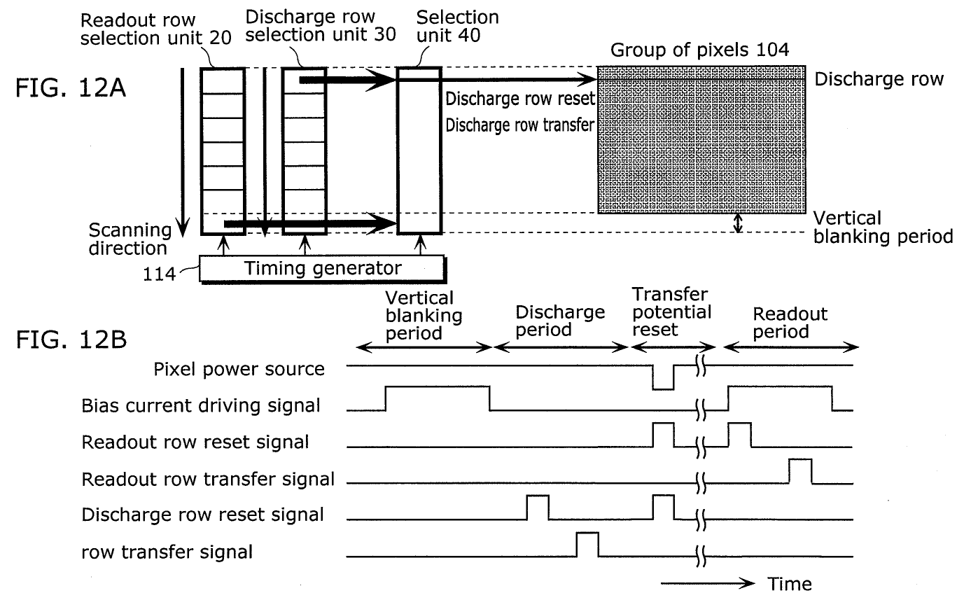

A basic configuration of the solid-state imaging devices according to the present embodiments is similar to that of the conventional solid-state imaging device shown in FIGS. 10 to 12, and the configuration is driven by the electronic shutter in the same manner. What differs, however, is that the configuration of the solid-state imaging devices according to the present embodiments optimizes each timing for the electronic shutter to reset the FD unit, transfer the unnecessary charge from the PD unit to the FD unit, and supply the bias current for the readout of the signal charge, so that the occurrence of the image defect due to the image lag can be prevented.

Hereinafter, the same description that has been described in Background Art is not repeated, and the driving timing and its effects that characterize the present invention will be described in detail.

### FIRST EMBODIMENT

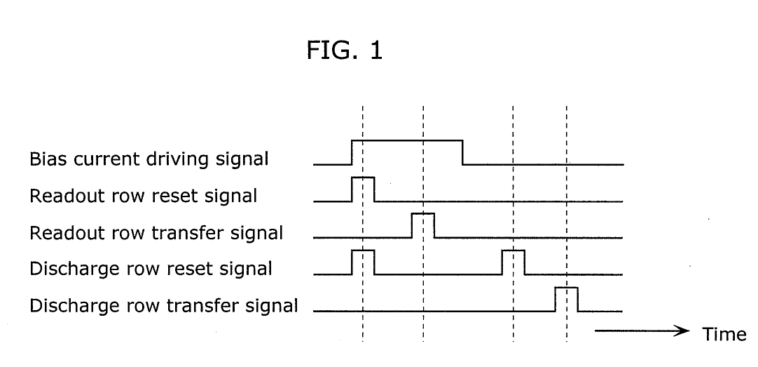

FIG. 1 is a timing chart showing driving timing of each driving signal in a solid-state imaging device according to a first embodiment of the present invention.

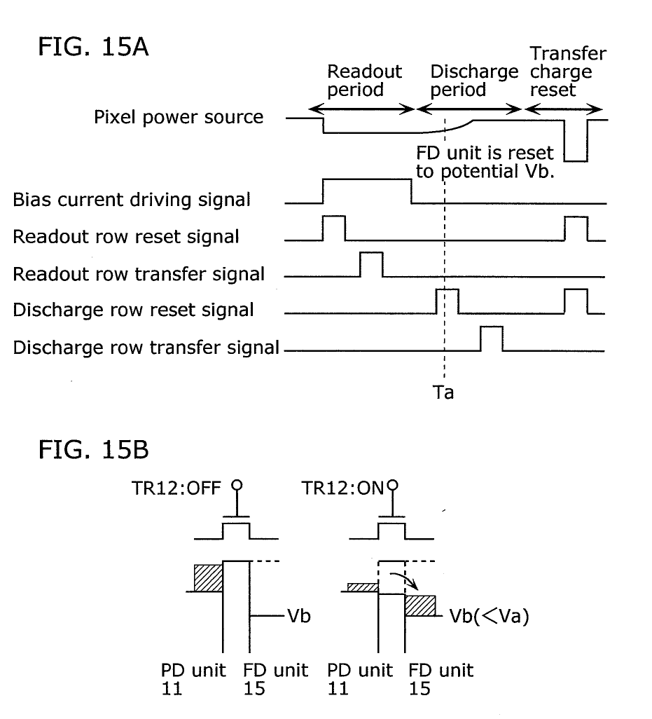

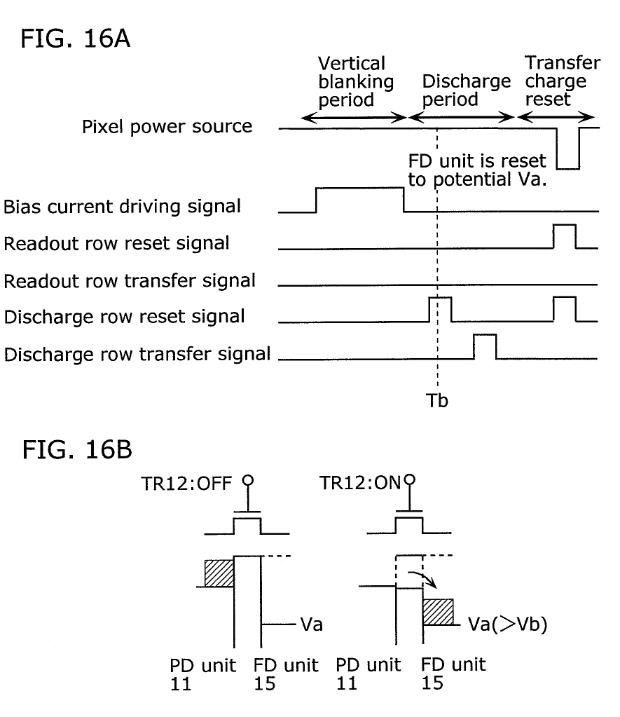

Compared with the conventional driving timing shown in FIG. 15, the driving timing differs in that while a bias current is supplied to readout a photocharge from a pixel circuit in a readout row, reset signal is provided to a discharge row selected by the discharge row selection unit 30.

Furthermore, employing such driving timing during a vertical blanking period enables an FD unit of the pixel circuit where an unnecessary charge is discharged during a valid pixel period and an FD unit of another pixel circuit where the unnecessary charge is discharged during the vertical blanking period to be reset to the same potential.

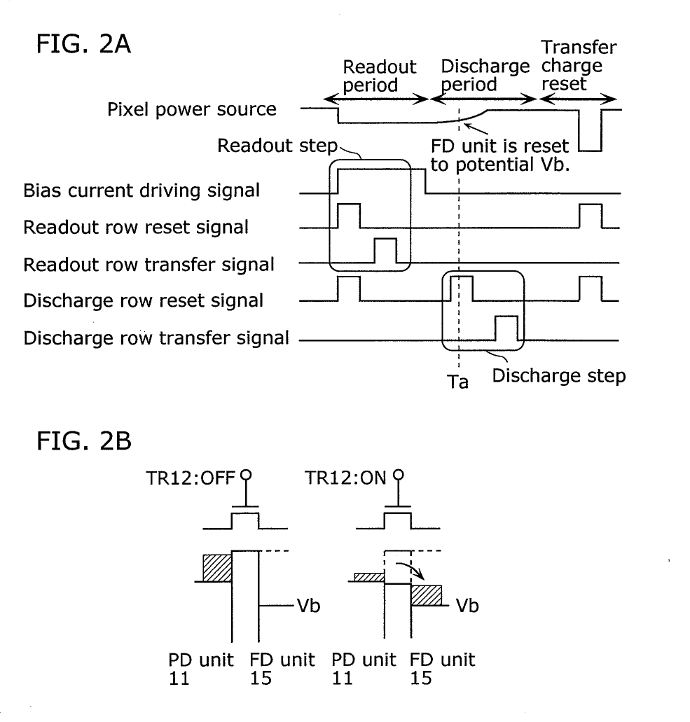

FIG. 2A is a timing chart showing time change of a pixel power source and each driving signal during the valid pixel period in the solid-state imaging device according to the first embodiment, and FIG. 2B is a diagram depicting potential change in the FD unit caused by discharge row transfer signal shown in FIG. 2A.

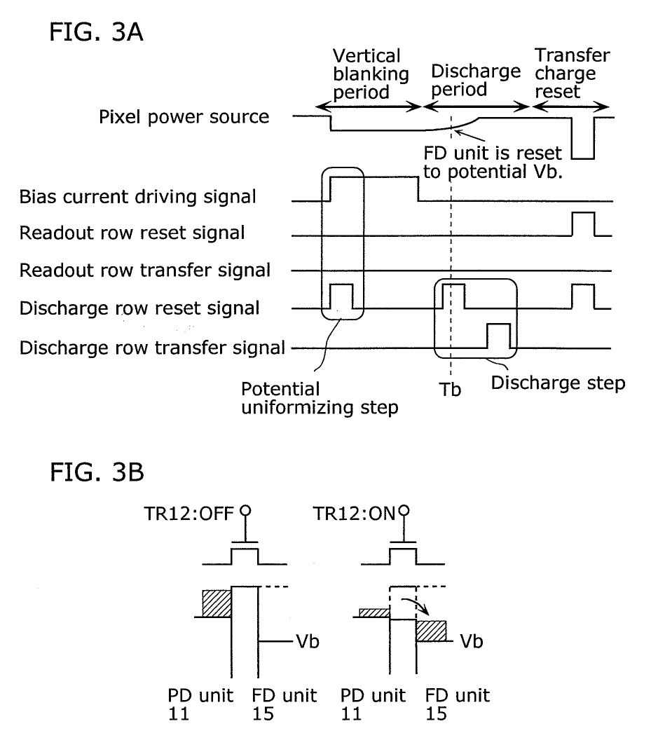

FIG. 3A is a timing chart showing the time change of the pixel power source and each driving signal during the vertical blanking period in the solid-state imaging device according to the first embodiment, and FIG. 3B is a diagram depicting the potential change in the FD unit caused by the discharge row transfer signal shown in FIG. 3A.

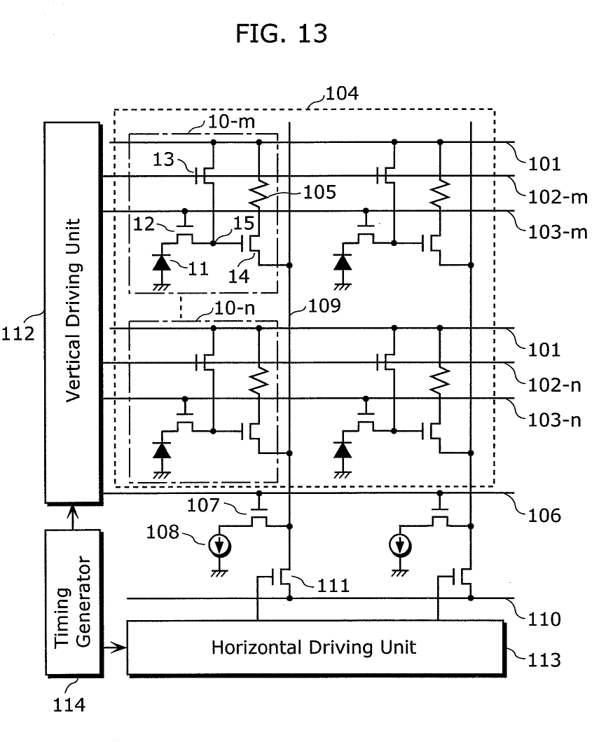

During the valid pixel period, as shown in FIG. 2A, in the readout step, while the bias current is supplied, the readout row reset signal and the readout row transfer signal are provided so that the signal charge is readout from the readout row. Consequently, an electrical current is flown in the resistance component 105 shown in FIG. 13, and the potential of the pixel power source drops.

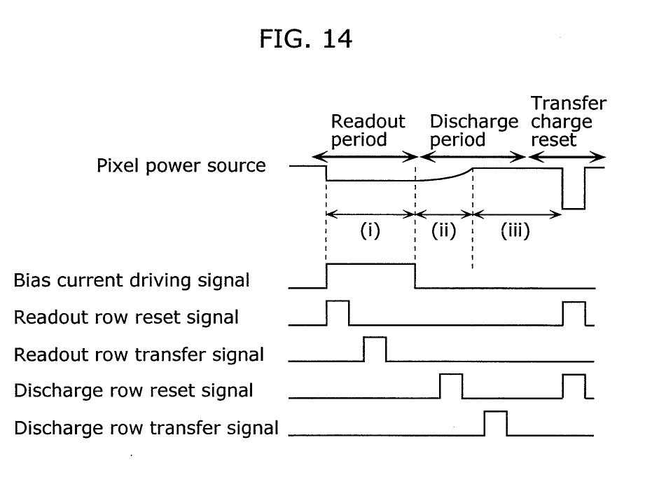

Subsequently, in the discharge step, at a time Ta shown in FIG. 2A, similar to the period (ii) shown in FIG. 14, the lowered potential of the pixel power source in the FD unit in the discharge row is reset to a potential Vb, which is in transition to a normal potential, by the discharge row reset signal. This operation is also performed in the related art.

On the other hand, during the vertical blanking period, as shown in FIG. 3A, in the potential uniformizing step, while the bias current is supplied to the vertical signal output line 109, the discharge row reset signal is provided, thereby turning on the reset transistor 13 of the pixel circuit in the discharge row. Consequently, the potential of the FD unit 15 becomes that of the pixel power source 101 and the electrical current flows in the amplification transistor 14 so that the resistance component 105 causes the potential drop in the pixel power source 101.

After this, in the discharge step, while the bias current is not supplied, the discharge row reset signal is provided again. The FD unit 15 is reset from the lowered potential of the pixel power source to the potential Vb, which is in transition to a normal potential, and the FD unit 15 is reset to reset potential Vb that is the same reset potential in the reset operation shown in FIG. 2A.

As described above, according to the first embodiment, in the case where the discharge step is performed independently without ensuing the readout step, the potential uniformizing step for resetting the charge accumulation unit of the pixel circuit in the discharge row to the potential of the common power source while supplying the bias current is performed prior to the discharge step. Accordingly, this causes the FD unit 15 in the row where the unnecessary charge is discharged during the valid pixel period and the FD unit 15 in another row where the unnecessary charge is discharged during the vertical blanking period to be reset to the same potential. Therefore, as shown between FIG. 2B and FIG. 3B, when discharging the unnecessary charge, the difference in the residual charge is eliminated so that the occurrence of the image defect due to the image lag can be prevented.

Note that the discharge row reset signal in the potential uniformizing step is preferably provided at the relatively equal timing with the discharge row reset signal in the readout step.

What is meant by the relatively equal timing may be: at least the length of a period in which each discharge row reset signal is provided is equal; further, an interval between a period in which each discharge row reset signal is provided and a period in which subsequent discharge row reset signal is provided is equal; and, concerning each discharge row reset signal, a period in which the discharge reset signal is provided overlaps with a period in which bias current driving signal is provided.

It is conceivable that the potential of the pixel power source is lowered with a time constant under the influence of the bias current and the resistance component. Even in such case, relatively synchronizing the timings in which each discharge row reset signal is provided can remove a variation in an amount of lowering the pixel power source.

### SECOND EMBODIMENT

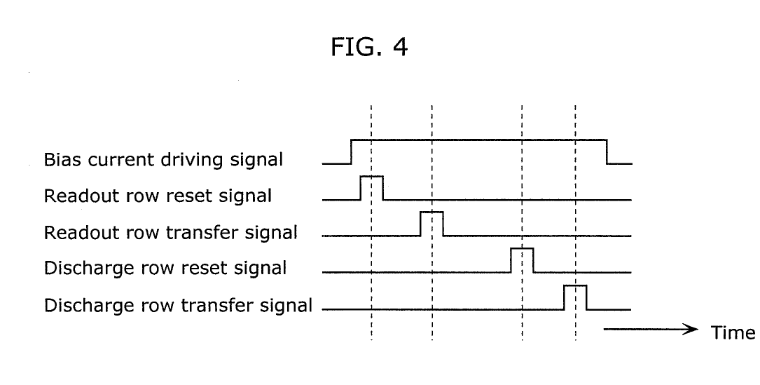

FIG. 4 is a timing chart showing driving timing of each driving signal in a solid-state imaging device according to a second embodiment of the present invention.

Compared with the conventional driving timing shown in FIG. 15, the driving timing differs in that bias current driving signal is provided not only during a readout period in which readout row reset signal and readout row transfer signal are provided but also during a discharge period in which discharge row reset signal and discharge transfer signal are provided.

Consequently, the same bias current is supplied through the bias current control transistor 107 and the constant current source 108 to the vertical signal output line 109 of each row during a period in which the reset signal is provided to a readout row and a period in which the reset signal is provided to a discharge row.

Employing such driving timing enables the FD unit of the pixel circuit where the unnecessary charge is discharged during the valid pixel period and the FD unit of another pixel circuit where the unnecessary charge is discharged during the vertical blanking period to be reset to the same potential.

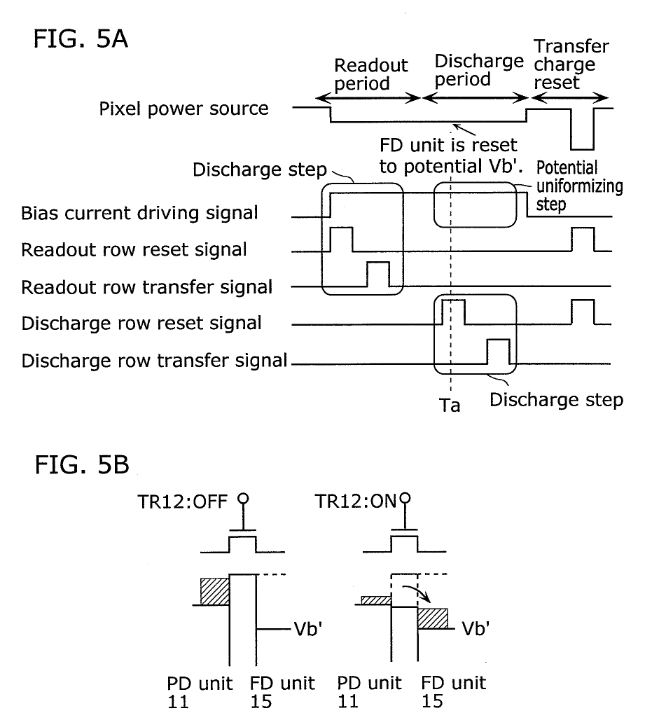

FIG. 5A is a timing chart showing time change of a pixel power source and each driving signal during the valid pixel period in the solid-state imaging device according to the second embodiment, and FIG. 5B is a diagram depicting potential change in the FD unit caused by the discharge row transfer signal shown in FIG. 5A.

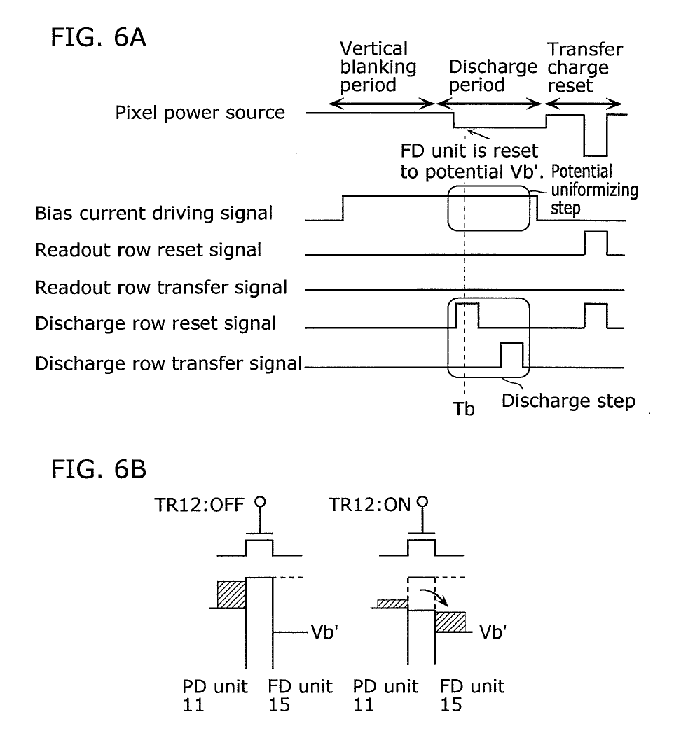

FIG. 6A is a timing chart showing the time change of the pixel power source and each driving signal during the vertical blanking period in the solid-state imaging device according to the second embodiment, and FIG. 6B is a diagram depicting the potential change in the FD unit caused by the discharge row transfer signal shown in FIG. 6A.

During the valid pixel period, as shown in FIG. 5A, while the discharge row reset signal is provided in the discharge step, the bias current driving signal is provided in the potential uniformizing step. Consequently, the potential of the FD unit 15 becomes that of the pixel power source 101 and the electrical current flows in the amplification transistor 14 so that the resistance component 105 causes the potential drop in the pixel power source 101. The FD unit 15 is reset to the lowered potential Vb′.

On the other hand, during the vertical blanking period, as shown in FIG. 6A, while the discharge row reset signal is provided in the discharge step, the bias current driving signal is provided in a charge uniformizing step. Consequently, the FD unit 15 is reset to the potential Vb′ of the pixel power source.

That is to say, the FD unit 15 is reset to the same potential Vb′ at the timing shown in FIG. 5A and the timing shown in FIG. 6A. As described above, according to the second embodiment, while the FD unit of the pixel circuit in the discharge row is reset in the discharge step, supplying the bias current in the charge uniformizing step resets, to the same potential, the FD unit 15 in the discharge row where the unnecessary charge is discharged during the valid pixel period and the FD unit 15 in another discharge row where the unnecessary charge is discharged during the vertical blanking period. Consequently, as shown between FIG. 5B and FIG. 6B, when discharging the unnecessary charge, the difference in the residual charge is eliminated so that the occurrence of the image defect due to the image lag can be prevented.

### THIRD EMBODIMENT

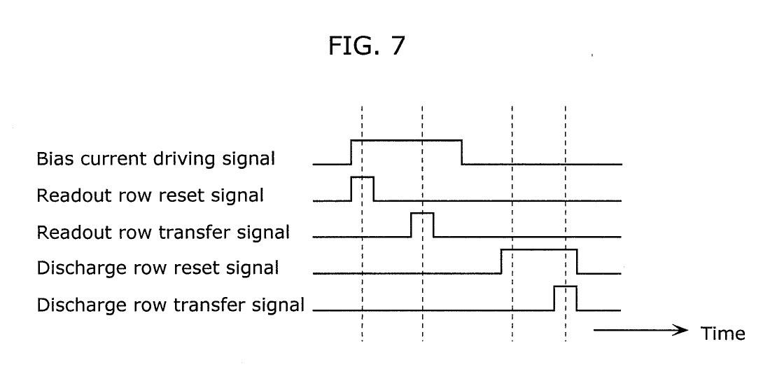

FIG. 7 is a timing chart showing driving timing of each driving signal in a solid-state imaging device according to a third embodiment of the present invention.

This operation timing differs from the conventional timing shown in FIG. 15 in that a period for providing discharge row reset signal is postponed or extended to a period in which the potential of the pixel power source returns to the normal potential. As an example, a period for providing the reset signal may be extended at least until provision of the transfer signal starts.

Employing such driving timing enables the FD unit of the pixel circuit where the unnecessary charge is discharged during the valid pixel period and the FD unit of another pixel circuit where the unnecessary charge is discharged to be reset to the same potential.

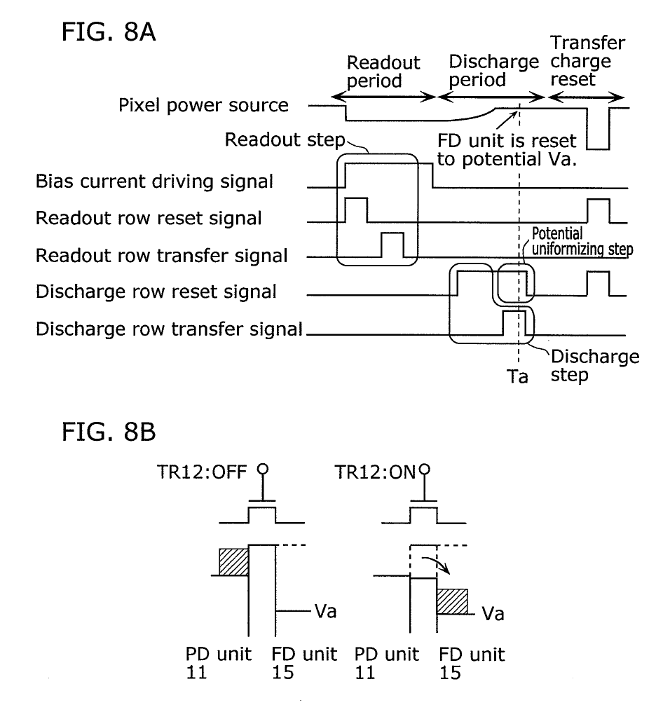

FIG. 8A is a timing chart showing time change of a pixel power source and each driving signal during the valid pixel period in the solid-state imaging device according to the third embodiment, and FIG. 8B is a diagram depicting potential change in the FD unit caused by discharge row transfer signal shown in FIG. 8A.

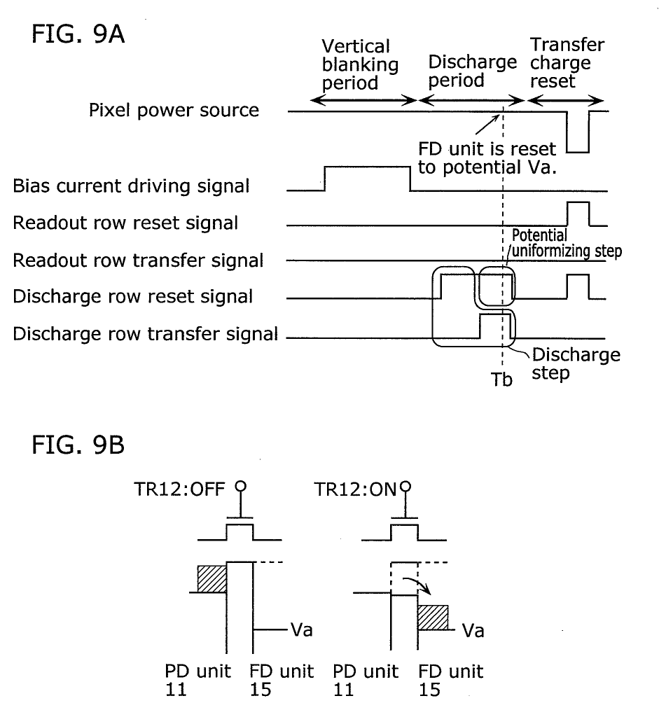

FIG. 9A is a timing chart showing the time change of the pixel power source and each driving signal during the vertical blanking period in the solid-state imaging device according to the third embodiment, and FIG. 9B is a diagram describing the potential change in the FD unit caused by the discharge row transfer signal shown in FIG. 9A.

During the valid pixel period, as shown in FIG. 8A, providing readout row reset signal in the readout step causes the potential of the pixel power source to drop. However, since the discharge row reset signal in the potential uniformizing step is sufficiently long and is provided after extending to a period in which the potential of the pixel power source is returned to the normal potential Va, the FD unit 15 is reset to the normal potential Va.

On the other hand, during the vertical blanking period, as shown in FIG. 9A, since no electrical current flows in the amplification transistors 14 both in the readout row and the discharge row, the potential of the pixel power source does not drop. Therefore, the FD unit 15 is reset to the normal potential Va of the power source.

As described above, according to the third embodiment, since a period for resetting the charge accumulation unit of the pixel circuit in the discharge row in the discharge step is extended until at least discharging the photocharge generated in the photoelectric conversion unit in the pixel circuit starts, the FD unit 15 in the discharge row where the unnecessary charge is discharged during the valid pixel period and the FD unit 15 in another discharge row where the unnecessary charge is discharged during the vertical blanking period are reset to the same potential. As a result, as shown between FIG. 8B and FIG. 9B, the difference in the residual charge when discharging the unnecessary charge is eliminated so that the occurrence of the image defect due to the image lag can be prevented.

Note that three patterns of the driving timing shown in the first to third embodiments may be employed separately or combined for use.

As described above, by merely optimizing the timing of the driving signal, the driving method of the solid-state imaging device according to the present invention prevents the image defect due to the image lag at low cost and with accuracy without adding a new driving circuit or power source to the device.

### INDUSTRIAL APPLICABILITY

The driving method of the solid-state imaging device according to the present invention can be applied to a solid-state imaging device performing the electronic shutter operation.

1. A driving method for use in a solid-state imaging device including a plurality of pixel circuits which are arranged in rows and columns and have a common power source, and each of which has a photoelectric conversion unit and a charge accumulation unit, said driving method comprising steps of:
reading out, to the outside of the pixel circuit, a photocharge generated at a photoelectric conversion unit in a pixel circuit in a
readout row, after resetting a potential of the charge accumulation unit in the pixel circuit to a potential of the common power source while supplying a bias current to the pixel circuit for readout, the photocharge being transferred to the charge accumulation unit as a signal charge;
discharging a photocharge generated at a photoelectric conversion unit in a pixel circuit in a discharge row that is to be a readout row later, after resetting a potential of a charge accumulation unit in the pixel circuit to a potential of the common power source, the photocharge being transferred to the charge accumulation unit as an unnecessary charge; and
uniformizing a potential of the charge accumulation unit to be reset in said discharging in the case where said discharging is executed following said reading out and in the case where said discharging is executed independently.

2. The driving method according to claim 1,
wherein said uniformizing includes: resetting the potential of the charge accumulation unit in the pixel circuit to the potential of the common power source, prior to said discharging, while supplying the bias current to the pixel circuit in the discharge row, in the case where said discharging is executed independently.

3. The driving method according to claim 2,
wherein said reading out includes: resetting the potential of the charge accumulation unit in the pixel circuit to the potential of the common power source; and subsequently reading out the photocharge generated in the photoelectric conversion unit in the pixel circuit in the readout row, the photocharge being transferred to the charge accumulation unit, and
said uniformizing includes resetting the charge accumulation unit in the pixel circuit in the discharge row at a timing which is relatively equal to a timing for resetting the charge accumulation unit in the pixel circuit in the readout row in said reading out.

4. The driving method according to claim 1,
wherein said uniformizing includes providing the bias current to the pixel circuit while resetting the charge accumulation unit in the pixel circuit in the discharge row in said discharging.

5. The driving method according to claim 1,
wherein said uniformizing includes extending a period in which the charge accumulation unit in the pixel circuit in the discharge row is reset in said discharging at least until discharging of the photocharge generated in the photoelectric conversion unit in the pixel circuit starts.

6. The driving method according to claim 1, each of the pixel circuits further includes: a reset switch that
is connected between the common power source and the charge accumulation unit; and a transfer switch that is connected between the photoelectric conversion unit and the charge accumulation unit,
providing driving signal to the reset switch causes the charge accumulation unit to be reset, and
providing driving signal to the transfer switch causes photocharge to be transferred from the photoelectric conversion unit to the charge accumulation unit.

7. A solid-state imaging device comprising:
a plurality of pixel circuits which are arranged in rows and columns, and each of which has a photoelectric conversion unit and a charge accumulation unit and receives a common power source,
a readout row selecting unit operable to select each row sequentially as a readout row where photocharge generated in the photoelectric conversion unit in the pixel circuit is to be readout as signal charge,
a discharge row selecting unit operable to select a discharge row that is to be a readout row later,
a bias current source that provides a bias current to readout the photocharge from the plurality of the pixel circuits in accordance with driving signal,
a controlling unit operable to: provide, to the pixel circuit in the selected readout row, reset signal that resets a potential of the charge accumulation unit in the pixel circuit to a potential of the common power source as well as transfer signal that transfers, as signal charge, the photocharge generated in the photoelectric conversion unit in the pixel circuit, while providing the driving signal that makes the bias current source to supply the bias current;
provide, to the pixel circuit in the selected discharge row, the reset signal that resets a potential of the charge accumulation unit in the pixel circuit to a potential of the common power source as well as the transfer signal that transfers, as unnecessary charge, the photocharge generated in the photoelectric conversion unit in the pixel circuit; and
provide potential uniformizing signal to uniformize a potential of the charge accumulation unit to be reset in accordance with the reset signal provided to the discharge row, in the case where the reset signal and the transfer signal to the discharge row are provided following the reset signal and the transfer signal to the readout row and in the case where the reset signal and the transfer signal to the discharge row are provided independently.
